(19) United States
(12) Patent Application Publication
(10) Pub. No.: US 2026/0140443 A1
(43) Pub. Date: May 21, 2026

(54) RESIST COMPOSITION AND PATTERNING PROCESS

(71) Applicant: SHIN-ETSU CHEMICAL CO., LTD., Tokyo (JP)

(72) Inventors: Shun KIKUCHI, Joetsu-shi (JP); Kousuke Ohyama, Joetsu-shi (JP); Satoshi Kusama, Joetsu-shi (JP); Ryo Nishikawa, Joetsu-shi (JP); Masaki Ohashi, Joetsu-shi (JP)

(73) Assignee: SHIN-ETSU CHEMICAL CO., LTD., Tokyo (JP)

(21) Appl. No.: 19/386,440

(22) Filed: Nov. 12, 2025

(30) Foreign Application Priority Data
Nov. 19, 2024 (JP) 2024-201885

(51) Int. Cl. G03F 7/004; G03F 7/00; G03F 7/20

(52) U.S. Cl. CPC G03F 7/0045; G03F 7/0035; G03F 7/2004

(57) ABSTRACT

The present invention is the resist composition includes a compound represented by the following general formula (1) and a solvent. This can provide a resist composition that exhibits excellent sensitivity, stability, and ease of handling for photolithography using a high-energy beam, particularly EB lithography and EUV lithography, as well as a patterning process that uses the resist composition.

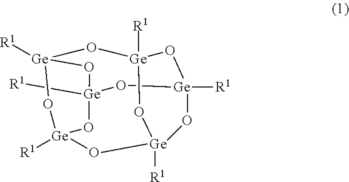

### TECHNICAL FIELD

The present invention relates to a resist composition and a patterning process.

### BACKGROUND ART

As the IoT market expands, demands for higher integration, higher speeds, and lower power consumption in LSIs are increasing, leading to rapid progress in miniaturization of pattern rules. Logic devices, in particular, are driving this miniaturization. The most cutting-edge miniaturization technology is ArF immersion lithography, with double patterning, triple patterning, and quadruple patterning being used to mass-produce 10 nm node devices, and research is underway to develop 7 nm node devices using next-generation extreme ultraviolet (EUV) lithography with a wavelength of 13.5 nm.

As miniaturization progresses, image blurring due to acid diffusion has become a problem (Non-Patent Document 1). In order to ensure resolution in fine patterns in generations with a processing dimension of 45 nm and beyond, it has been suggested that controlling acid diffusion is important, in addition to improving dissolution contrast, as has been proposed previously (Non-Patent Document 2). However, chemically amplified resist compositions increase sensitivity and contrast through acid diffusion, and thus attempts to minimize acid diffusion by lowering the post-exposure bake (PEB) temperature or shortening the PEB time result in significant decreases in sensitivity and contrast.

Suppressing acid diffusion by adding an acid generator that generates bulky acid is effective. Therefore, it has been proposed to copolymerize an onium salt acid generator with a polymerizable olefin into a polymer. However, for resist film patterning in generations with a processing dimension of 16 nm and beyond, it is considered that chemically amplified resist compositions will not be able to form patterns due to acid diffusion, and the development of non-chemically amplified resist compositions is desired.

Polymethyl methacrylate (PMMA) is an example of a material for non-chemically amplified resist compositions. PMMA is a positive resist material in which the main chain undergoes chain scission by electron beam (EB) or EUV irradiation, reducing the molecular weight thereof and improving the solubility thereof in organic solvent developers, but PMMA does not have a ring structure, and thus has drawbacks such as low etching resistance and large amounts of outgassing during exposure.

Hydrogen silsesquioxane (HSQ) is a material used in negative resist compositions that becomes insoluble in alkaline developers due to crosslinking caused by a condensation reaction of silanols generated by EB or EUV irradiation. In addition, chlorine-substituted calixarenes also function as materials for negative resist compositions. These materials have a small molecular size before crosslinking and are free of blurring due to acid diffusion, resulting in low edge roughness and extremely high resolution, making them used as pattern transfer materials to indicate the resolution limit of exposure apparatus. However, these materials have insufficient sensitivity and require further improvement.

One of the difficulties in developing materials for EUV lithography is the low number of photons used in EUV exposure. EUV energy is much higher than that of ArF excimer laser light, and the number of photons used in EUV exposure is one-fourteenth of that used in ArF exposure. Further, the dimensions of patterns formed with EUV exposure are less than half those achieved with ArF exposure. For this reason, EUV exposure is susceptible to variations in the number of photons. Variations in the number of photons in the extremely short-wavelength beam region are a physical phenomenon known as shot noise, and these effects cannot be eliminated. For this reason, so-called stochastics has attracted attention. While the effects of shot noise cannot be eliminated, methods for reducing them are being discussed. It has been observed that shot noise not only increases the critical dimension uniformity (CDU) and line width roughness (LWR), but also causes holes to become blocked with a probability of one in several million. Blocked holes cause poor electrical conduction and transistors not to operate, adversely affecting the performance of the entire device.

As a method for reducing the effects of shot noise on the resist side, inorganic resist compositions utilizing elements with high EUV absorption as the core have been proposed (Patent Document 1). However, while having relatively high sensitivity, the inorganic resist composition is still not sufficient for practical use and has many issues, such as insufficient solubility in solvents used in resist compositions, storage stability, and defects.

Non-Patent Document 3 proposes a negative resist composition using a tin compound. This is a non-chemically amplified resist composition containing tin, which is an element having high EUV light absorption, as a main component, and despite of improving stochastics and significantly improving sensitivity and resolution, the above resist composition has stability issues and is problematic in that the resist composition deteriorates during storage and the performance changes due to post-PEB hold (time-course from PEB to development (post-PEB delay (PPD))).

### CITATION LIST

### Patent Literature

Patent Document 1: JP 2015-108781 A

### Non-Patent Literature

Non-Patent Document 1: SPIE Vol. 5039 p. 1 (2003)
Non-Patent Document 2: SPIE Vol. 6520 p. 65203L-1 (2007)
Non-Patent Document 3: SPIE Vol. 9051 p. 90511B-1 (2014)

### SUMMARY OF INVENTION

### Technical Problem

The present invention has been made in view of the above circumstances, and an objective thereof is to provide a resist composition that exhibits excellent sensitivity, stability, and ease of handling in photolithography using a high-energy beam, particularly in EB lithography and EUV lithography, as well as a patterning process using the resist composition.

### Solution to Problem

To solve the above-described problems, the present invention provides a resist composition comprising a compound represented by the following general formula (1) and a solvent:

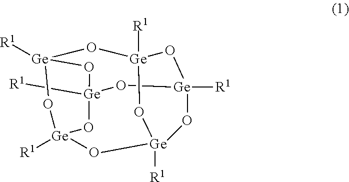

wherein R¹ is a halogen atom or a hydrocarbyl group having 1 to 10 carbon atoms and optionally including a heteroatom.

Such a resist composition can provide a resist composition that is stable, easy to handle, and has excellent sensitivity in photolithography using a high-energy beam, as well as a patterning process using the resist composition.

Further, it is preferable that the resist composition of the present invention includes a metal compound containing one or more metals selected from the group consisting of cobalt, nickel, copper, zinc, silver, indium, tin, antimony, tellurium, and platinum.

The metal atoms included in such metal compounds have high EUV absorption ability in EUV lithography, and thus adding these to the resist composition of the present invention results in a resist composition that also has excellent sensitivity and LWR.

Further, the present invention provides a patterning process, comprising the steps of: forming a resist film on a substrate using the resist composition of the present invention; exposing the resist film by using a high-energy beam; and developing the exposed resist film to form a resist pattern.

The resist composition of the present invention can be suitably used in a patterning process.

In addition, the patterning process preferably uses EB or EUV as the high-energy beam.

The resist composition of the present invention can be suitably used in a patterning process using EB or EUV as a high-energy beam.

### Advantageous Effects of Invention

The resist composition of the present invention has excellent sensitivity and favorable stability, particularly in EB lithography and EUV lithography, and thus is extremely useful for forming fine patterns.

### DESCRIPTION OF EMBODIMENTS

As described above, there has been a need for a resist composition that is highly sensitive, stable, and easy to handle in photolithography using a high-energy beam, as well as the development of a patterning process using such a resist composition.

As a result of extensive research into the above-described problems, the present inventors have found that a resist composition primarily composed of a germanium compound having a specific structure exhibits excellent sensitivity, produces a resist film with excellent stability, and is extremely effective for precise microfabrication, leading to the completion of the present invention.

That is, the present invention is a resist composition including a compound represented by the following general formula (1) and a solvent,

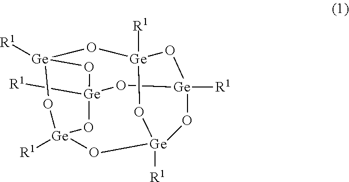

wherein R¹ is a halogen atom or a hydrocarbyl group having 1 to 10 carbon atoms and optionally including a heteroatom.

The present invention is described in detail below, but is not limited thereto.

### [Resist Composition]

The resist composition of the present invention includes a specific germanium compound and a solvent.

### [Germanium Compound]

The germanium compound is a compound represented by the following general formula (1):

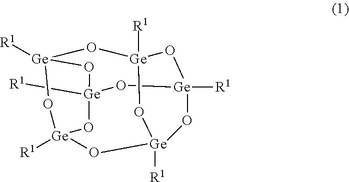

wherein R¹ is a halogen atom or a hydrocarbyl group having 1 to 10 carbon atoms and optionally including a heteroatom.

In the formula, R¹ is a halogen atom or a hydrocarbyl group having 1 to 10 carbon atoms, which may contain a heteroatom.

Examples of the halogen atom represented by R¹ include a fluorine atom, a chlorine atom, a bromine atom, and an iodine atom. The hydrocarbyl group having 1 to 10 carbon atoms represented by R¹ may be saturated or unsaturated, and may be linear, branched, or cyclic. Specific examples thereof include: alkyl groups having 1 to 10 carbon atoms such as a methyl group, an ethyl group, a propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group, and a n-decyl group; cyclic saturated hydrocarbyl groups having 3 to 10 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, and an adamantyl group; alkenyl groups such as a vinyl group and an allyl group; aryl groups having 6 to 10 carbon atoms such as a phenyl group and a naphthyl group; and groups obtained by combining these groups. In addition, a part or all of the hydrogen atoms of the hydrocarbyl group may be substituted with a group including a heteroatom such as an oxygen atom, a sulfur atom, a nitrogen atom, or a halogen atom, and a part of the —CH₂— groups of the hydrocarbyl group may be substituted with a group including a heteroatom such as an oxygen atom, a sulfur atom, or a nitrogen atom, and as a result, a hydroxy group, a cyano group, a halogen atom, a carbonyl group, an ether bond, a thioether bond, an ester bond, a sulfonate ester bond, a carbonate bond, a carbamate bond, a lactone ring, a sultone ring, a carboxylic anhydride (—C(═O)—O—C(═O)—), and the like may be included. Among these, R¹ is preferably a hydrocarbyl group having 1 to 4 carbon atoms.

Specific examples of the germanium compound represented by the above general formula (1) include, but are not limited to, the following:

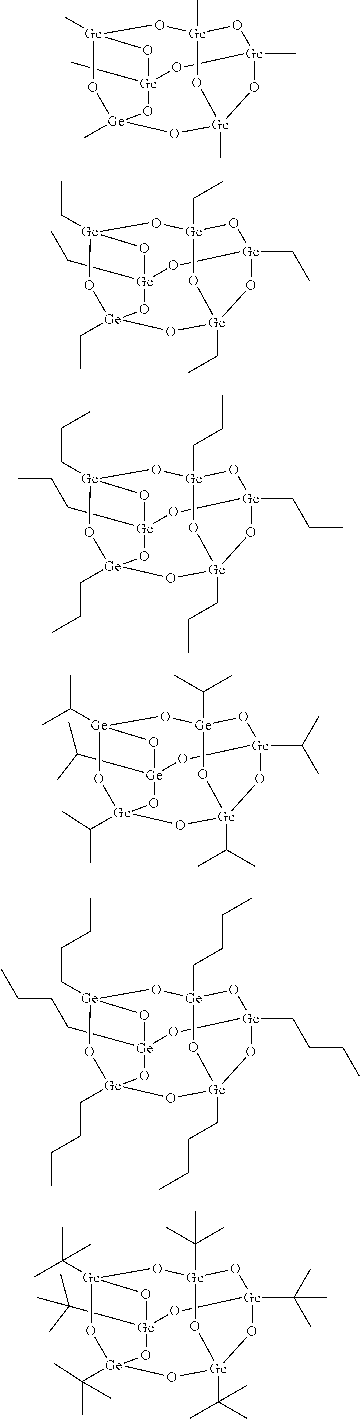

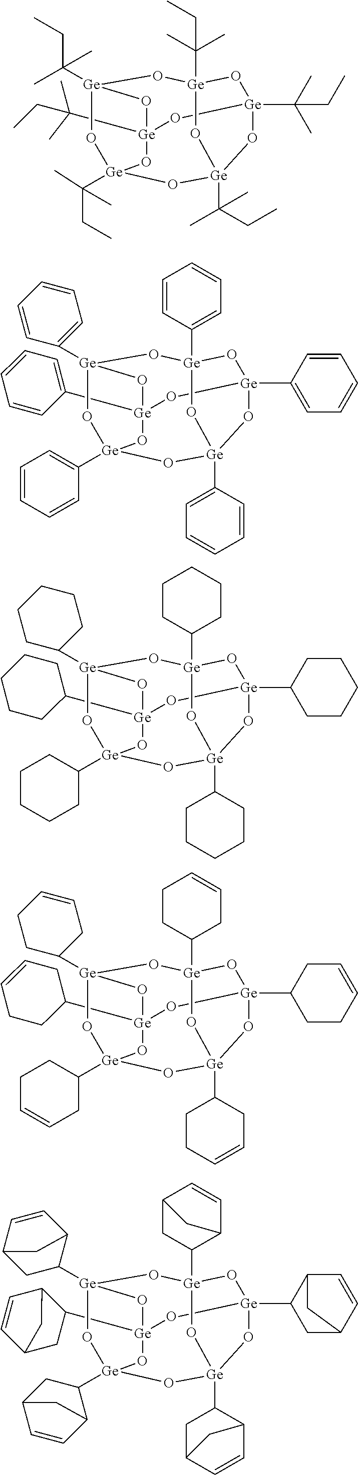

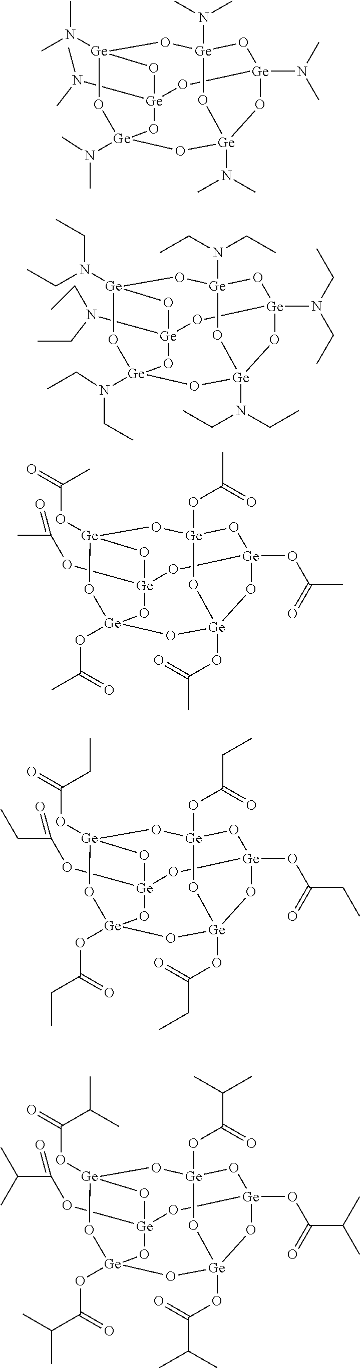

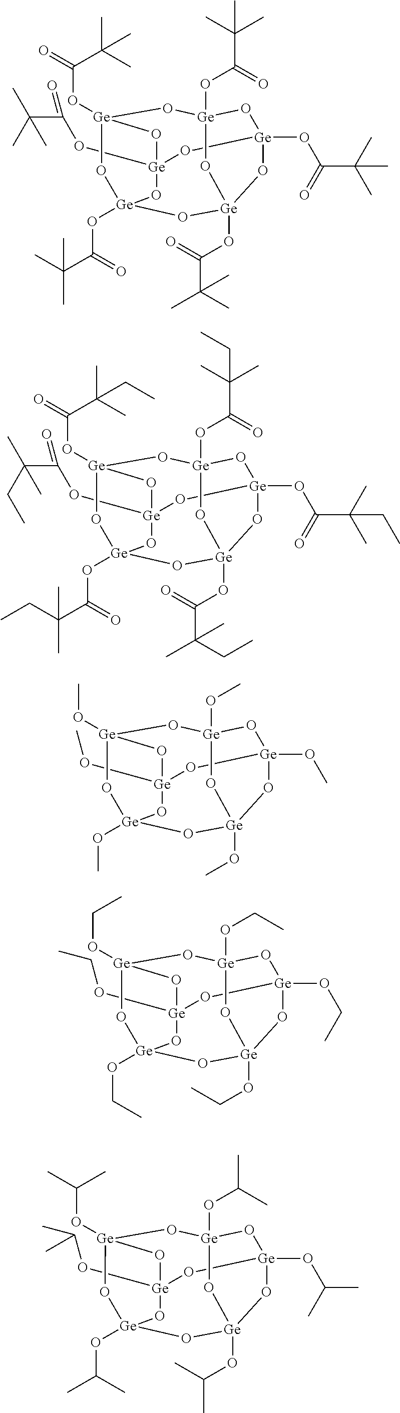

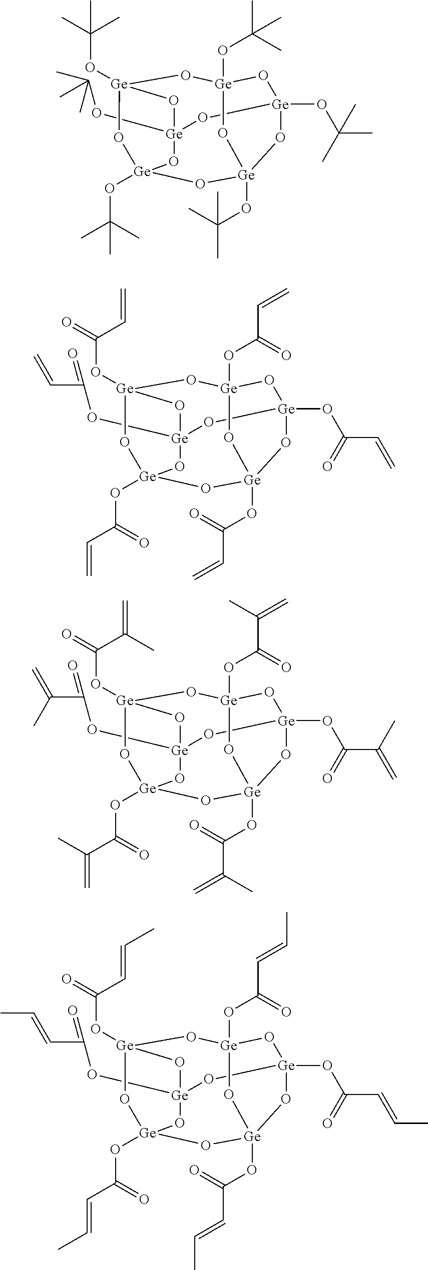

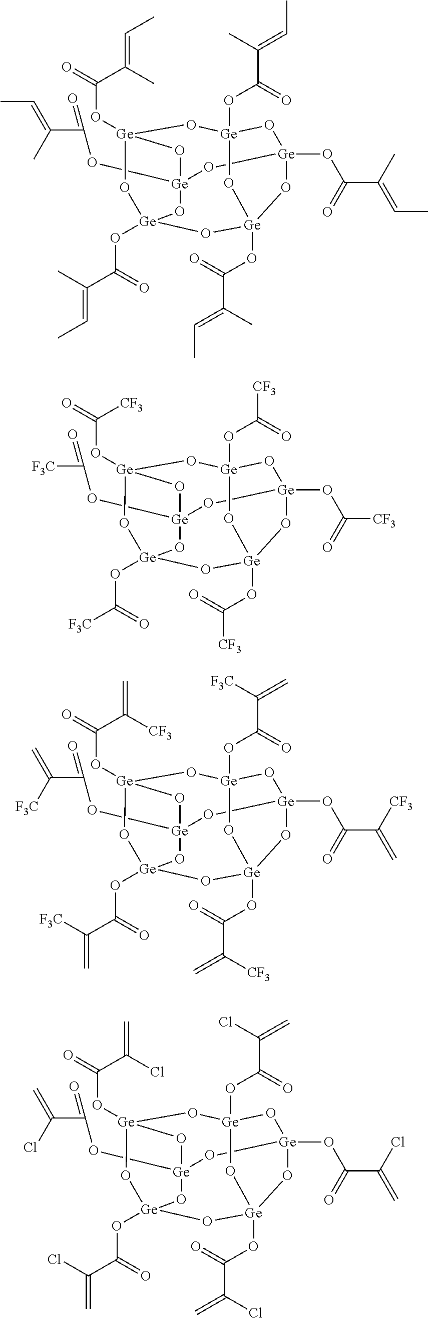

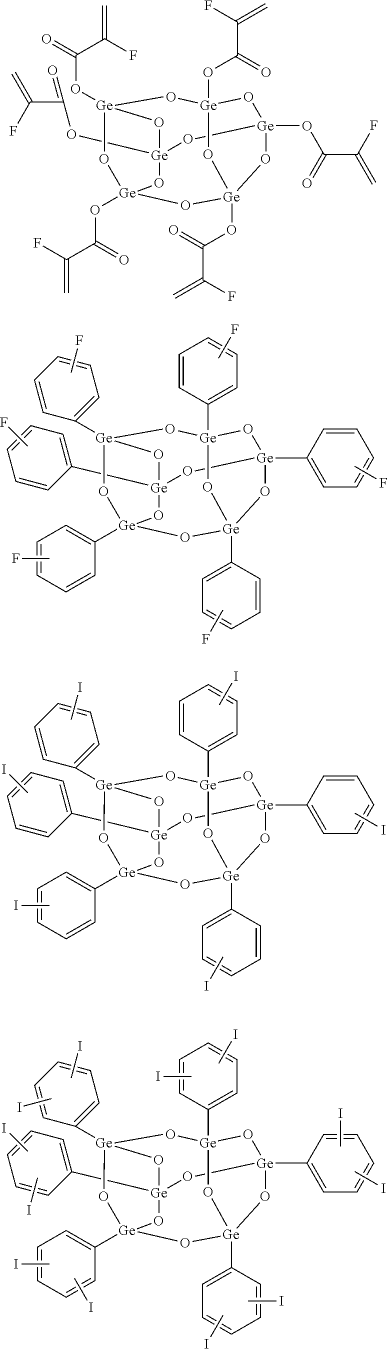

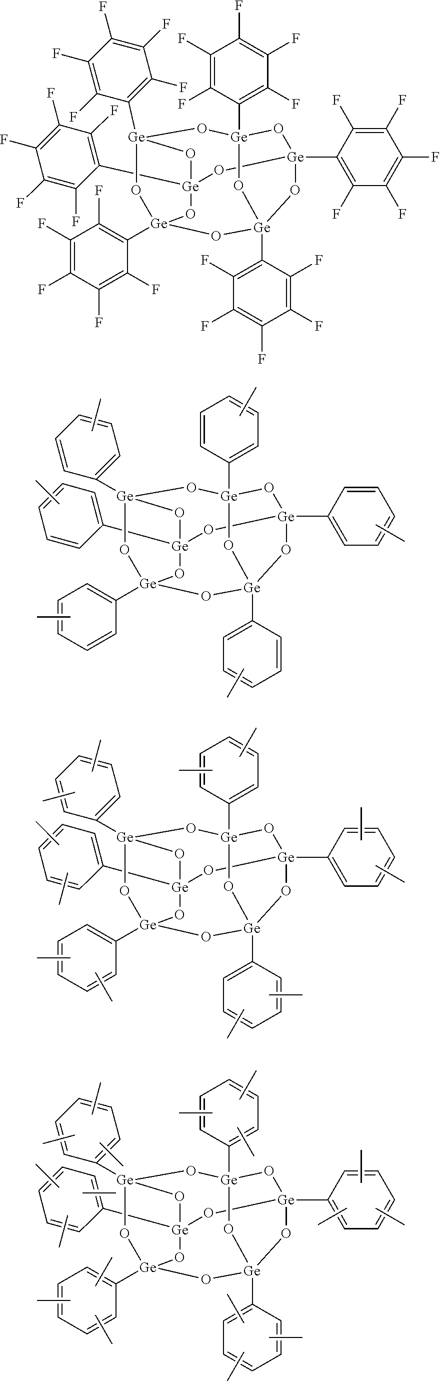

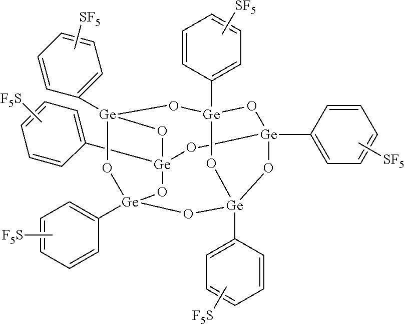

The above germanium compounds may be used singly or in combination of two or more.

### [Solvent]

The resist composition of the present invention includes a solvent. An organic solvent is preferable. The organic solvent is not particularly limited as long as it dissolves the germanium compound, and can be used to form a film. Examples of such organic solvents include: ketones such as cyclohexanone and methyl-2-n-pentyl ketone; alcohols such as 3-methoxybutanol, 3-methyl-3-methoxybutanol, 1-methoxy-2-propanol, 1-ethoxy-2-propanol, and diacetone alcohol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, methyl 2-hydroxyisobutyrate, tert-butyl acetate, cyclohexyl acetate, tert-butyl propionate, and propylene glycol mono-tert-butyl ether acetate; lactones such as γ-butyrolactone; carboxylic acids such as acetic acid and propionic acid; aromatics such as toluene, xylene, cresol, anisole, and benzotrifluoride; halogenated hydrocarbons such as dichloromethane, chloroform, and carbon tetrachloride; and mixtures of these solvents.

The content of the solvent is preferably 200 to 20,000 parts by mass, and more preferably 500 to 15,000 parts by mass, based on 100 parts by mass of the germanium compound.

It is assumed that the resist composition of the present invention exhibits contrast by changing the development resistance between exposed and unexposed portions due to photodecomposition of the germanium compound as the main component, and subsequent aggregation or crosslinking reaction between the partially destroyed germanium compounds. This reaction is not catalytic, and thus the resist composition of the present invention functions as a non-chemically amplified resist composition. As a result, it is possible to resolve fine areas that are difficult to pattern with conventional chemically amplified resist compositions containing multi-component polymers as the main component. In addition, the germanium compound converges into a thermally stable structure, and thus also has excellent storage stability. In addition, there is no significant change in performance over time after PEB.

The germanium-carbon bond of the germanium compound is energetically weak, which is considered to result in efficient cleavage reactions upon light irradiation.

### [Metal Compound]

The resist composition of the present invention may include a metal compound containing one or more metals selected from cobalt, nickel, copper, zinc, silver, indium, tin, antimony, tellurium, and platinum.

The content of the metal compound is preferably 5 to 50 parts by mass based on 100 parts by mass of the germanium compound.

In EUV lithography, the metal atoms have high EUV absorption ability, and thus adding these atoms to the resist composition improves stochastics, resulting in a resist composition with excellent sensitivity and LWR.

Several types of the metal compounds can be used in combination to adjust the properties, particularly the radiation absorption.

The metal compound is preferably an organometallic compound. Any structure is acceptable for the organometallic compound, and compounds having a small amount of organic compound components in the structure and high EUV absorption capabilities as a whole molecule are preferable, and it is desirable for the compound to be soluble in an organic solvent that dissolves resist and be spin-coated onto a substrate in an amorphous state.

### [Photoacid Generator]

The resist composition of the present invention may include a photoacid generator as a component other than the germanium compound and the solvent. The use of a photoacid generator is expected to generate acid in the exposed portions and promote the crosslinking reaction of the germanium compound. Such photoacid generators are not particularly limited as long as they generate acid upon exposure to a high-energy beam, and conventional photoacid generators known for use in chemically amplified resist compositions can be used, and photoacid generators that generate sulfonic acid, imide acid, or methide acid are particularly preferable. Examples of the suitable photoacid generators include a sulfonium salt, an iodonium salt, sulfonyldiazomethane, N-sulfonyloxyimide, and an oxime-o-sulfonate-type acid generator. Specific examples of the photoacid generator include those described in paragraphs [0122] to [0142] of JP 2008-111103 A and those described in paragraphs [0127] to [0193] of JP 2022-163697 A.

When the resist composition of the present invention includes the photoacid generator, the content thereof is preferably 0.01 to 20 mass % of the total solids content. Note that, in this specification, “solids” refers collectively to all components of the resist composition excluding the solvent. The photoacid generator may be used singly, or may be used in combination of two or more.

### [Radical Scavenger]

The resist composition of the present invention may include a radical scavenger as another component. Adding a radical scavenger can control the photoreaction during photolithography and adjust sensitivity.

As the radical scavenger, hindered phenols, quinones, hindered amines, and thiol compounds can be used. Specific examples of the hindered phenols include dibutylhydroxytoluene and 2,2′-methylenebis(4-methyl-6-tert-butylphenol). Specific examples of the quinones include 4-methoxyphenol(methoquinone) and hydroquinone. Specific examples of the hindered amines include 2,2,6,6-tetramethylpiperidine and 2,2,6,6-tetramethylpiperidine-N-oxy radical. Specific examples of the thiol compounds include dodecanethiol and hexadecanethiol.

When the resist composition of the present invention includes the radical scavenger, the content thereof is preferably 0.01 to 10 mass % of the total solids content. The radical scavenger may be used singly, or may be used in combination of two or more.

### [Surfactant]

The resist composition of the present invention may also include a surfactant as another component. As examples of the surfactant, those described in JP 2010-215608 A and JP 2011-16746 A can be referred. Among these, FC-4430 (manufactured by 3M Company), Surflon (registered trademark) S-381 (manufactured by AGC Seimi Chemical Co., Ltd.), Olfine (registered trademark) E1004 (manufactured by Nissin Chemical Industry Co., Ltd.), KH-20, KH-30 (manufactured by AGC Seimi Chemical Co., Ltd.), and oxetane ring-opening polymers represented by the following general formula (surf-1) are preferable.

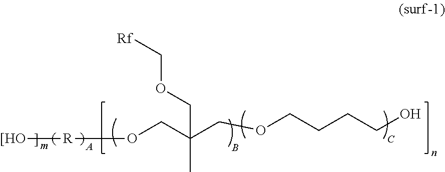

In the above general formula (surf-1), R represents a divalent to tetravalent aliphatic group having 2 to 5 carbon atoms. Examples of the divalent aliphatic group include ethylene, 1,4-butylene, 1,2-propylene, 2,2-dimethyl-1,3-propylene, and 1,5-pentylene groups, and examples of the trivalent and tetravalent groups include the following:

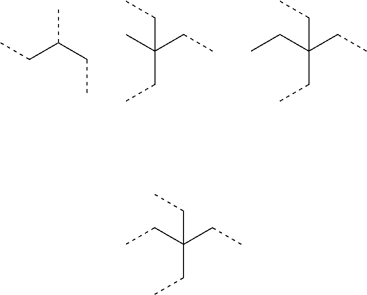

wherein the dashed lines represent attachment points and are partial structures derived from glycerol, trimethylolethane, trimethylolpropane, and pentaerythritol, respectively.

Among these, the 1,4-butylene group and the 2,2-dimethyl-1,3-propylene group are preferable.

In the above general formula (surf-1), Rf is a trifluoromethyl group or a pentafluoroethyl group, preferably the trifluoromethyl group. m is an integer of 0 to 3, n is an integer of 1 to 4, and the sum of n and m is the valence of R, which is an integer of 2 to 4. A is 1. B is an integer of 2 to 25, preferably an integer of 4 to 20. C is an integer of 0 to 10, preferably 0 or 1. In addition, the order of the structural units in the general formula (surf-1) is not specified, and the structural units may be bonded in blocks or randomly. Regarding the production of surfactants based on partially fluorinated oxetane ring-opening polymers, details are provided in U.S. Pat. No. 5,650,483 A and the like.

When the resist composition of the present invention includes the surfactant, the content thereof is preferably 0.001 to 20 parts by mass, more preferably 0.1 to 10 parts by mass, based on 100 parts by mass of the germanium compound. The surfactant may be used singly or in combination of two or more.

### [Patterning Process]

When the resist composition of the present invention is used in the manufacture of various integrated circuits, known lithography techniques can be applied. The patterning process is preferably a process including the steps of forming a resist film on a substrate using the resist composition of the present invention, exposing the resist film by using a high-energy beam, and developing the exposed resist film to form a resist pattern.

The resist composition of the present invention is applied to a substrate for integrated circuit manufacturing (Si, SiO₂, SiN, SiON, TiN, WSi, BPSG, SOG, organic anti-reflective coating, and the like) or a substrate for mask circuit manufacturing (Cr, Cro, CrON, MoSi₂, SiO₂, and the like) using an appropriate application method such as spin coating, roll coating, flow coating, dip coating, spray coating, or doctor coating to a applied film thickness of 0.01 to 2 μm. Then, the film is heated on a hot plate. Preferably, the film is heated at 60 to 200° C. for 10 seconds to 30 minutes, and more preferably, at 80 to 180° C. for 30 seconds to 20 minutes to form a resist film.

Examples of the high-energy beam include ultraviolet beam, far ultraviolet beam, EB, EUV with a wavelength of 3 to 15 nm, X-rays, soft X-rays, excimer laser light, γ-rays, and synchrotron beam. When ultraviolet beam, far ultraviolet beam, EUV, X-rays, soft X-rays, excimer laser light, γ-rays, synchrotron beam, and the like are used as the high-energy beam, irradiation is performed directly or using a mask to form the desired pattern, with an exposure dose of preferably approximately 1 to 200 mJ/cm², and more preferably approximately 10 to 150 mJ/cm². When EB is used as the high-energy beam, drawing is performed directly or using a mask to form the desired pattern, with an exposure dose of preferably approximately 0.1 to 5000 μC/cm², and more preferably approximately 0.5 to 4000 μC/cm². Note that, the resist composition of the present invention is particularly suitable for fine patterning using EB or EUV, among other high-energy beams.

PEB may be performed to accelerate or complete the reaction after photodecomposition. It is preferable to perform PEB on a hot plate or in an oven after exposure, preferably at 30 to 200° C. for 10 seconds to 30 minutes, more preferably at 60 to 180° C. for 30 seconds to 20 minutes.

Development after exposure or PEB can be either wet development or dry development. In the case of the wet development, alkali development or organic solvent development can be used, but the organic solvent development is preferable when forming a pattern using the resist composition of the present invention. Wet development is performed on the exposed resist film by conventional methods such as a dipping method, a puddling method, or a spraying method, preferably for 3 seconds to 3 minutes, more preferably 5 seconds to 2 minutes, to form the desired pattern. The resist composition of the present invention is a negative type, and thus the irradiated portions become insoluble in the developer, while the unexposed portions dissolve.

Examples of the organic solvents used as developers include alkaline aqueous solutions such as aqueous tetramethylammonium hydroxide solution and aqueous tetrabutylammonium hydroxide solution; and organic solvents such as 2-octanone, 2-nonanone, 2-heptanone, 3-heptanone, 4-heptanone, 2-hexanone, 3-hexanone, diisobutyl ketone, 5-methyl-2-hexanone, methylcyclohexanone, acetophenone, methylacetophenone, isopropyl alcohol, isoamyl alcohol, n-butanol, tert-butyl alcohol, tert-pentyl alcohol, n-pentanol, cyclohexanol, formic acid, acetic acid, propionic acid, propyl acetate, butyl acetate, isobutyl acetate, pentyl acetate, butenyl acetate, isopentyl acetate, cyclohexyl acetate, 4-tert-butylcyclohexyl acetate, octyl acetate, isobornyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, 2-phenylethyl acetate, 1-propanol, 3-methoxybutanol, 3-methyl-3-methoxybutanol, 1-methoxy-2-propanol, 1-ethoxy-2-propanol, 3-methyl-1-butanol, diacetone alcohol, 4-methyl-2-pentanol, 3-methylcyclohexanol, 3,5,5-trimethylhexyl alcohol, 2,6-dimethyl-4-heptanol, toluene, anisole, ε-caprolactone, octane, nonane, decane, undecane, and dodecane. These developers may be used singly or in combination of two or more.

After development, rinse is performed as necessary. Preferable rinse solutions are solvents that are miscible with the developer but do not dissolve the resist film. Such solvents preferably used include alcohols having 3 to 10 carbon atoms, ether compounds having 8 to 12 carbon atoms, alkanes, alkenes, alkynes having 6 to 12 carbon atoms, and aromatic solvents.

Specific examples of the alcohols having 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol.

Specific examples of the ether compounds having 8 to 12 carbon atoms include di-n-butyl ether, diisobutyl ether, di-sec-butyl ether, di-n-pentyl ether, diisopentyl ether, di-sec-pentyl ether, di-tert-pentyl ether, and di-n-hexyl ether.

Specific examples of the alkanes having 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Specific examples of the alkenes having 6 to 12 carbon atoms include hexene, heptene, octene, cyclohexene, methylcyclohexene, dimethylcyclohexene, cycloheptene, and cyclooctene. Specific examples of the alkyne having 6 to 12 carbon atoms include hexyne, heptyne, and octyne.

Specific examples of the aromatic solvents include toluene, xylene, ethylbenzene, isopropylbenzene, tert-butylbenzene, and mesitylene.

Rinsing can reduce resist pattern collapse and defect generation. In addition, rinsing is not necessarily required, and eliminating rinsing can reduce the amount of solvent used.

Dry development can also be used as a development method in the patterning process of the present invention. Dry development is a process in which either exposed or unexposed portions are removed by a gas etching process without using a developer. In the present invention, the desired pattern can be formed by removing the unexposed portions using an etching gas. For dry etching, a gas including oxygen, hydrogen, ammonia, or halogen, with dilution gases such as nitrogen, helium, argon, carbon dioxide, or carbon monoxide is preferably used.

### EXAMPLE

The present invention will be described in detail below using examples and comparative examples, but the present invention is not limited to these.

### [1] Synthesis of Germanium Compound (G-1)

A germanium compound (G-1) was synthesized with reference to Chemistry Letters 2002, pp. 1124-1125, to obtain the germanium compound (G-1) shown in the following structural formula.

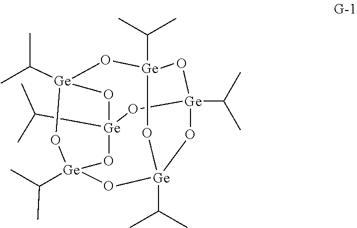

### [2] Preparation of Resist Compositions

### Examples 1-1 to 1-13 and Comparative Example 1-1

The germanium compound and other components were dissolved in a solvent in the compositions and amounts blended shown in Table 1 below, and the resulting solutions were filtered through a 0.2 μm Teflon (Registered Trademark) filter to prepare resist compositions (R-01 to R-13) of the present invention and a comparative resist composition (RC-01).

TABLE 1

| | | Germanium | | | | |
|---|---|---|---|---|---|---|
| | Resist | compound | Component A | Component B | Component C | Solvent |
| | composition | (parts by mass) | (parts by mass) | (parts by mass) | (parts by mass) | (parts by mass) |
| Example 1-1 | R-01 | G-1(20) | | | | PGMEA (1000) |
| Example 1-2 | R-02 | G-1(20) | M-1(5) | | | PGMEA (1000) |
| Example 1-3 | R-03 | G-1(20) | M-2(5) | | | PGMEA (1000) |
| Example 1-4 | R-04 | G-1(20) | M-3(13) | | | PGMEA (1000) |
| Example 1-5 | R-05 | G-1(20) | M-4(13) | | | PGMEA (1000) |
| Example 1-6 | R-06 | G-1(20) | M-5(6) | | | PGMEA (1000) |
| Example 1-7 | R-07 | G-1(20) | M-6(12) | | | PGMEA (1000) |
| Example 1-8 | R-08 | G-1(20) | M-7(12) | | | PGMEA (1000) |
| Example 1-9 | R-09 | G-1(20) | M-8(13) | | | PGMEA (1000) |
| Example 1-10 | R-10 | G-1(20) | M-9(10) | | | PGMEA (1000) |
| Example 1-11 | R-11 | G-1(20) | M-10(5) | | | PGMEA (1000) |
| Example 1-12 | R-12 | G-1(20) | M-1(5) | P-1(19) | | PGMEA (1000) |
| Example 1-13 | R-13 | G-1(20) | M-1(5) | | Sc-1 (0.01) | PGMEA (1000) |
| Comparative | RC-01 | M-1(18) | | | | 4M2P (1000) |
| Example 1-1 | | | | | | |

In Table 1 above, a component A is a metal compound, a component B is a photoacid generator, and a component C is a radical scavenger. The compounds used as the component A (M-1 to M-10) have the following structural formulae. M-1 (tin compound) was synthesized according to Angewandte Chemie, International Edition (2017), 56 (34), 10140-10144, while M-2 to M-10 were purchased commercially. Details of the compounds used as the components B and C are as follows.

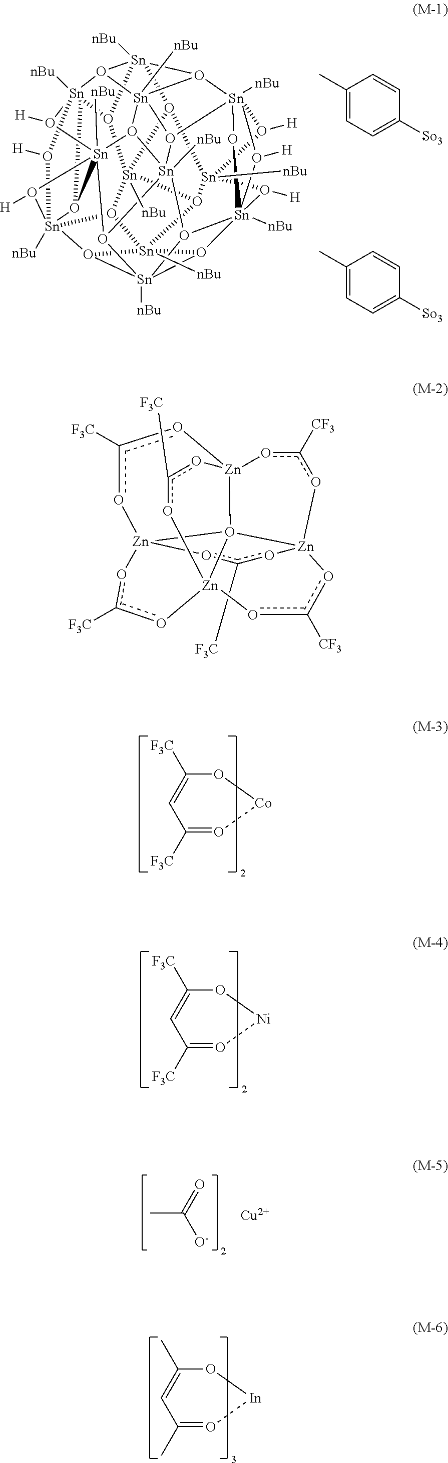

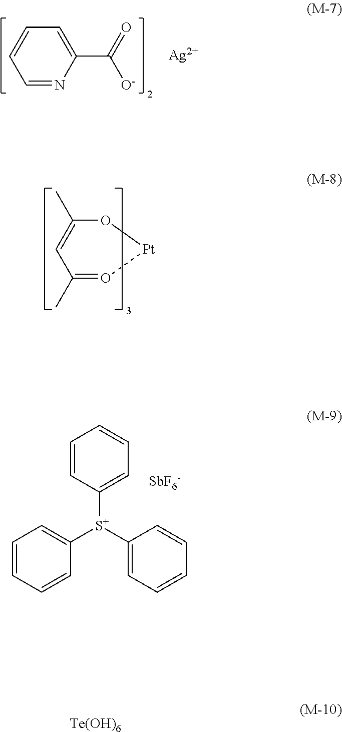

P-1: Triphenylsulfonium tosylate
Sc-1: Dibutylhydroxytoluene
Solvent: PGMEA (propylene glycol monomethyl ether acetate)
4M2P (4-methyl-2-pentanol)
   [3] EB lithography evaluation

### Examples 2-1 to 2-13, and Comparative Example 2-1

Each resist composition (R-01 to R-13, and RC-01) was spin-coated onto a Si substrate on which a 60-nm-thick anti-reflective coating (DUV-42) manufactured by Nissan Chemical Corporation had been formed, and prebaked on a hot plate at 100° C. for 60 seconds to form a 40-nm-thick resist film. The resist film was exposed using an EB lithography system manufactured by Elionix Inc. (ELS-F125, accelerating voltage 125 kV), subjected to PEB on a hot plate for 60 seconds at the temperature listed in Table 2, and developed for 30 seconds using 2-heptanone as the developer to form a pattern. As a result, a negative-tone line-and-space (LS) pattern with a space width of 20 nm and a pitch of 40 nm was obtained. The obtained LS patterns were evaluated for sensitivity, LWR, limiting resolution, and post-exposure delay stability according to the evaluation methods below. The results are shown in Table 2.

### [Sensitivity Evaluation]

The LS pattern described above was observed using an electron microscope to determine the optimal exposure dose Eop (μC/cm²) required to obtain an LS pattern with a space width of 20 nm and a pitch of 40 nm. This was determined as the sensitivity.

### [LWR Evaluation]

Dimensions of the LS pattern obtained by irradiation at the optimal exposure dose were measured at 10 locations along the longitudinal direction of the space width using a CD-SEM (CG-5000) manufactured by Hitachi High-Technologies Corporation, and from the results, three times value (3σ) of the standard deviation (σ) was calculated and used as the LWR. The smaller this value is, the lower the roughness and the more uniform the pattern with consistent space width.

### [Limiting Resolution Evaluation]

The limiting line width (nm) that can be resolved when forming a pattern by gradually increasing the exposure dose from the optimal exposure dose was determined using a CD-SEM (CG-6300) manufactured by Hitachi High-Technologies Corporation, and this was determined as the limiting resolution (nm). This value is smaller, showing that the limiting resolution is better and the finer pattern can be formed.

### [Post-Exposure Delay Stability Evaluation]

After exposure at the optimal exposure dose, PEB and development were performed under the conditions described above. Patterned wafers were produced by development without post-PEB delay (PPD0h), and by development after 6 hours of post-PEB delay (PPD6h). The line widths of these wafers were measured using a CD-SEM CG-6300 manufactured by Hitachi High-Technologies Corporation to determine the line width (CD) and its change (ΔPPD) due to post-exposure delay. The results are shown in Table 2.

TABLE 2

| | | | | | Limiting | PPD 0 h | PPD 6 h | ΔPPD |
|---|---|---|---|---|---|---|---|---|
| | Resist | PEB | EoP | LWR | resolution | CD | CD | CD |
| | composition | (° C.) | (μC/cm²) | (nm) | (nm) | (nm) | (nm) | (nm) |
| Example 2-1 | R-01 | 150 | 2800 | 3.8 | 14.5 | 19.9 | 19.9 | 0 |
| Example 2-2 | R-02 | 150 | 3000 | 3.6 | 13.3 | 20.0 | 20.8 | 0.8 |
| Example 2-3 | R-03 | 150 | 2800 | 3.4 | 14.0 | 20.1 | 20.2 | 0.1 |
| Example 2-4 | R-04 | 150 | 2800 | 3.4 | 13.8 | 20.2 | 20.5 | 0.3 |
| Example 2-5 | R-05 | 150 | 2800 | 3.6 | 13.5 | 20.0 | 20.6 | 0.6 |
| Example 2-6 | R-06 | 150 | 2900 | 3.6 | 13.2 | 20.1 | 20.5 | 0.4 |
| Example 2-7 | R-07 | 150 | 2900 | 3.6 | 13.6 | 20.1 | 20.6 | 0.5 |
| Example 2-8 | R-08 | 150 | 2900 | 3.6 | 13.8 | 20.1 | 20.5 | 0.4 |
| Example 2-9 | R-09 | 150 | 2900 | 3.6 | 14.0 | 19.9 | 20.6 | 0.7 |
| Example 2-10 | R-10 | 150 | 3000 | 3.8 | 13.7 | 20.1 | 20.1 | 0 |
| Example 2-11 | R-11 | 150 | 2800 | 3.6 | 13.5 | 20.2 | 20.5 | 0.3 |
| Example 2-12 | R-12 | 150 | 2800 | 4.0 | 15.0 | 20.1 | 20.1 | 0 |
| Example 2-13 | R-13 | 150 | 2900 | 3.7 | 14.0 | 20.2 | 20.2 | 0 |
| Comparative | RC-01 | 170 | 3200 | 4.7 | 18.6 | 20.1 | 25.2 | 5.1 |
| Example 2-1 | | | | | | | | |

The results shown in Table 2 demonstrate that Examples 2-1 to 2-13, which used resist compositions of the present invention (R-01 to R-13), exhibited excellent LWR and critical resolution when forming negative patterns using EB lithography with organic solvent development. Further, there was little change in CD after post-exposure delay, confirming stability after patterning. In contrast, it is found that Comparative Example 2-1, which used resist composition (RC-01), exhibited inferior LWR, critical resolution, and post-exposure delay.

### [4] Storage Stability Evaluation

### Examples 3-1 to 3-13 and Comparative Example 3-1

Each resist composition (R-01 to R-13 and RC-01) was left at room temperature (20±5° C.) for a specified period of time, and visual inspection was performed to determine whether precipitation occurred. In this case, samples that could be stored for six months or more without precipitation were marked with o, and samples that showed precipitation in less than six months were marked with x. The results are shown in Table 3.

TABLE 3

| | Resist composition | Storage stability |
|---|---|---|
| Example 3-1 | R-01 | ∘ |
| Example 3-2 | R-02 | ∘ |
| Example 3-3 | R-03 | ∘ |
| Example 3-4 | R-04 | ∘ |
| Example 3-5 | R-05 | ∘ |
| Example 3-6 | R-06 | ∘ |
| Example 3-7 | R-07 | ∘ |
| Example 3-8 | R-08 | ∘ |
| Example 3-9 | R-09 | ∘ |
| Example 3-10 | R-10 | ∘ |
| Example 3-11 | R-11 | ∘ |
| Example 3-12 | R-12 | ∘ |
| Example 3-13 | R-13 | ∘ |
| Comparative | RC-01 | x |
| Example 3-1 | | |

The results shown in Table 3 above demonstrate that Examples 3-1 to 3-13, which used resist compositions of the present invention (R-01 to R-13), exhibited excellent storage stability and were easy to handle. In contrast, Comparative Example 3-1, which used resist composition (RC-01), exhibited poor storage stability.

### [5] EUV Lithography Evaluation (Line and Space Pattern)

### Examples 4-1 and 4-2

Each resist composition (R-01 and R-02) of the present invention was spin-coated onto a Si substrate on which a 20-nm-thick silicon-containing spin-on hard mask SHB-A940 (43% silicon by mass) manufactured by Shin-Etsu Chemical Co., Ltd. had been formed and prebaked (PAB) on a hot plate at 100° C. for 60 seconds to produce a 40-nm-thick resist film. The resist film was exposed to a 36 nm line and space (LS) 1:1 pattern using an EUV scanner NXE3400 manufactured by ASML Holding N.V. (NA 0.33, σ 0.9, 90-degree dipole illumination), followed by PEB on a hot plate at the temperature listed in Table 4 for 60 seconds, and the resulting pattern was then developed in 2-heptanone for 30 seconds to form an LS pattern with a space width of 18 nm and a pitch of 36 nm.

The resulting resist patterns were evaluated as follows. The results are shown in Table 4.

### [Sensitivity Evaluation]

The LS pattern was observed using a CD-SEM (CG-6300) manufactured by Hitachi High-Technologies Corporation, and the optimal exposure dose Eop (mJ/cm²) required to obtain an LS pattern with a space width of 18 nm and a pitch of 36 nm was obtained, and this was determined as the sensitivity.

### [LWR Evaluation]

Dimensions of the LS pattern obtained by irradiation at the optimal exposure dose were measured at 10 locations along the longitudinal direction of the space width using a CD-SEM (CG-6300) manufactured by Hitachi High-Technologies Corporation, and from the results, the LWR (nm) was calculated as three times value (3σ) of the standard deviation (σ). As this value is smaller, the less roughness and the more uniform space width pattern is obtained.

### [Limiting Resolution Evaluation]

The limiting line width (nm) that can be resolved when forming a pattern by gradually increasing the exposure dose from the optimal exposure dose required to form the LS pattern was determined using a CD-SEM (CG-6300) manufactured by Hitachi High-Technologies Corporation, and this was determined as the limiting resolution (nm). This value is smaller, showing that the limiting resolution is better and the finer pattern can be formed.

TABLE 4

| | | | | | Limiting |
|---|---|---|---|---|---|
| | Resist | PEB | EoP | LWR | resolution |
| | composition | (° C.) | (mJ/cm²) | (nm) | (nm) |
| Example 4-1 | R-01 | 150 | 50 | 3.8 | 14 |
| Example 4-2 | R-02 | 150 | 42 | 3.2 | 13 |

The results shown in Table 4 above demonstrate that Examples 4-1 and 4-2, which used resist compositions of the present invention (R-01 and R-02), exhibited excellent LWR and limiting resolution when forming negative patterns using EUV lithography with organic solvent development. Further, it has been found that the addition of a metal compound with high EUV light absorption made it possible to form patterns with excellent sensitivity, LWR, and resolution.

Note that the present invention is not limited to the above-described embodiments. The above-described embodiments are merely illustrative, and any configurations that are substantially identical to the technical concept described in the claims of the present invention and that exhibit similar effects are within the technical scope of the present invention.

1. A resist composition comprising:
a compound represented by the following general formula (1) and a solvent, 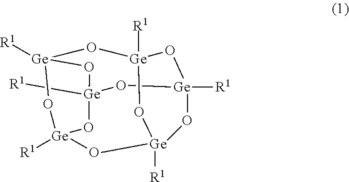
wherein R¹ is a halogen atom or a hydrocarbyl group having 1 to 10 carbon atoms and optionally including a heteroatom.

2. The resist composition according to claim 1, wherein the resist composition includes a metal compound containing one or more metals selected from the group consisting of cobalt, nickel, copper, zinc, silver, indium, tin, antimony, tellurium, and platinum.

3. A patterning process comprising the steps of:
forming a resist film on a substrate using the resist composition according to claim 1;
exposing the resist film by using a high-energy beam; and
developing the exposed resist film to form a resist pattern.

4. A patterning process comprising the steps of:
forming a resist film on a substrate using the resist composition according to claim 2;
exposing the resist film by using a high-energy beam; and
developing the exposed resist film to form a resist pattern.

5. The patterning process according to claim 3, wherein the high-energy beam is EB or EUV.
